(19) United States
(12) Patent Application Publication
(10) Pub. No.: US 2016/0173053 A1
(43) Pub. Date: Jun. 16, 2016

(54) POWER SHUNT ELECTROMAGNETIC INTERFERENCE FILTER

(71) Applicant: AMAZING MICROELECTRONIC CORP., New Taipei City (TW)

(72) Inventor: TUNG-YANG CHEN, HSINCHU COUNTY 30264 (TW)

(21) Appl. No.: 14/641,543

(22) Filed: Mar. 9, 2015

(30) Foreign Application Priority Data
Dec. 16, 2014 (TW) 103143866

(51) Int. Cl. H03H 7/01

(52) U.S. Cl. CPC H03H 7/0153; H03H 7/0138

(57) ABSTRACT

A power shunt EMI filter is electrically connected to a power feeding line of a main functional IC and other loads. The main functional IC driven by a power source supplied by the power feeding line generates an output voltage and an output current which are individually involved with an output voltage interference and an output current interference, and a phase difference exits there-in-between. A reference providing circuit generates a reference signal according to the output voltage interference and/or the output current interference. At least one adjust filtering circuit calculates eigenvalues of the output voltage interference and/or the output current interference according to the reference signal, such that the phase difference and amplitudes of the interferences are zero. Thus, an output voltage signal and current signal the load receives are DC signal without interferences.

This application claims priority for Taiwan patent application no. 103143866 filed on Dec. 16, 2014, the content of which is incorporated by reference in its entirely.

### BACKGROUND OF THE INVENTION

1. Field of the Invention

The present invention is related to an electromagnetic interference (EMI) filter, and more particularly to a power shunt EMI filter used to suppress the electromagnetic interferences occurred on the power source of an IC circuit.

2. Description of the Prior Art

Since printed circuit boards (PCB) are mostly involved in transferring a plurality of various signals, wherein each signal is constructed by the superposition of many different harmonic frequency signals, each harmonic frequency signal is not only affecting the quality of the signal being transferred, but also causing a lot of interferences between one signal to another. However, the factors which affect the signals are more than these. The complicated harmonic frequency signals that are coupled to a power source of the IC are also one of the main EMI factors. What causes these coupled-harmonic frequencies are mainly generated from the inner operation of a lot of logic circuits in the main functional IC. As such, these coupled-harmonic frequency signals are becoming the main sources of the electromagnetic interferences (EMI) of electronics devices nowadays. To solve these electromagnetic interferences on the power of PCB, a variety of capacitors and filters are commonly used for now.

However, since the design concept of signal integrity (SI) and power integrity (PI) of a printed circuit board must be well simulated and associated with the electrical characteristics of the main functional IC, its circuit board thereon and a setting of boundary conditions, thus it has become quite difficult nowadays. In order to achieve the co-simulation concept, it isn't always easy for system designers to fully acquire all signal and power information of the main functional IC. Besides, since the IC designers can only handle the well signal characteristics, when it comes to the system designing part, still nothing can be well controlled by them. While for these harmonic frequency signals coupled on the power system, the system and IC designs can hardly handle them since barely very little power characteristic model of main function IC is provided. Furthermore, in order to keep the price of electronic devices nowadays more competitive, a structure of printed circuit board are downed to four-layer boards from the original six-layer boards, and from four-layer boards to two-layer boards. Under circumstances like these, it has become more and more difficult to maintain the power integrity (PI) of a shrunk printed circuit board, and the capacitors and filter used in the prior arts are apparently not applicable anymore. As such, when trying to fix the electromagnetic interferences issues occurred on the power source of the printed circuit board, many system engineers still have to use the “try and error” methods to adjust the EMI to the least, which is not only less effective but also being both time and cost-consuming.

Furthermore, the electromagnetic interferences issues occurred on the power of PCB with a special harmonic frequency are generated by many different circuit block driving and sinking currents in main function IC. Therefore, the fact that a small-signal voltage and a small-signal current are not processing synchronously is formed. Moreover, when the small-signal voltage from functional IC passes through a capacitor at the power line path, its phase difference between the small-signal voltage and the small-signal current cannot be suppressed. The worse case is that, the peak of one current signal waveform from functional IC can be aligned to the valley of transition current signal waveform bypass capacitor which is completely 180 degree difference. Such a composition current will not only affect the electrical paths from this node to other paths (return path) on the printed circuit board to induce EMI issue, but also cause the larger voltage drop on the wires due to parasitic inductance effects. Thereby it will dramatically influent the voltage and current characteristics in a chain reaction

On account of all, it should be obvious that there is indeed an urgent need for the professionals in the field for a new EMI structure to be developed that can actively and aggressively suppress and eliminate the electromagnetic interference at the power source so as to solve the above-mentioned problems occurring in the prior design.

### SUMMARY OF THE INVENTION

In order to overcome the above-mentioned disadvantages, one major objective in accordance with the present invention is provided for a novel and creative power shunt EMI filter. By employing the novel power shunt EMI filter of the present invention, it can be utilized so as to successfully eliminate the electromagnetic interference at the power source. The power EMI filter of the present invention is shunted in connection with the power and ground of the main functional IC and then connected to PCB system power/ground rail and used for eliminating the harmonic frequency waveforms and electromagnetic interferences coupled at the power source.

Another objective in accordance with the present invention is provided for a novel power shunt EMI filter, wherein by calculating one eigenvalue of at least two voltages and currents equations of the circuit, an optimum filter structure which is composed of at least one resistor, capacitor, and/or inductor can be obtained. As such, it is believed that the proposed power shunt EMI filter is so much better than the previous strategy to use the “try and error” method and is advantageous of low production cost and minimal production time as well.

And yet another objective in accordance with the present invention is provided for a novel power EMI filter, which is shunted in connection to the power/ground source and the main functional IC. By employing the power shunt EMI filter of the present invention, it simply works well to eliminate the interferences having frequency range from 100 MHz up to several GHz on the power line, and still meanwhile maintain an excellent behavior of signal integrity (SI) and power integrity (PI).

For achieving the above mentioned objectives, the present invention provides a power shunt EMI filter, which comprises a reference providing circuit and at least one adjust second or more filtering circuit. The power shunt EMI filter of the present invention is electrically connected to a power feeding line of a main functional IC and other loads. After the main functional IC is driven by a power source supplied by the power feeding line, it starts to work and generates an output voltage and an output current on this power feeding line, wherein the output voltage is involved with an output voltage interference, and the output current is involved with an output current interference, respectively. Being affected by the power harmonics interferences generated by different function blocks in main functional chip, the non-synchronized phase exits between the output voltage interference and the output current interference.

According to one embodiment of the present invention, the transition voltage and current of operation circuits block are electrically coupled to the power of main functional IC and generates a reference signal according to the output voltage interference and the output current interference. The at least one adjust filtering circuit is connected parallel to the reference providing circuit, receives the reference signal and accordingly calculates the eigenvalues of the output voltage interference and/or the output current interference. By calculation, the phase difference between the output voltage interference and the output current interference can be adjusted to zero, and the amplitude of the output voltage interference and the output current interference can also be adjusted to zero as well. Therefore, an output voltage and output current that the power connected to other loads are merely direct current (DC) power without any interferences or harmonics involved.

Furthermore, the present invention may further comprises at least one first adjusting circuit, second adjusting circuit, third adjusting circuit or fourth adjusting circuit, which can be optionally disposed in the circuit. Since the first adjusting circuit, second adjusting circuit, third adjusting circuit and fourth adjusting circuit are all composed of passive elements (for example, resistors, inductor, and/or inductors), when a controlling switch is utilized to provide a dependent voltage-current curve based on the reference signal, the calculating of eigenvalues of the output voltage interference and/or the output current interference can be derived. Therefore, a purpose of eliminating the interferences from the power feeding line of the power source is successfully accomplished.

These and other objectives of the present invention will become obvious to those of ordinary skill in the art after reading the following detailed description of preferred embodiments.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIG. 1 shows a schematic drawing of the power shunt EMI filter according to the present invention.

FIG. 2 show a schematic drawing of the power shunt EMI filter comprising a plurality of adjust filtering circuits according to the present invention.

FIG. 3A shows a schematic drawing of the power shunt EMI filter in accordance with a first embodiment of the present invention.

FIG. 3B shows a schematic drawing of the power shunt EMI filter in accordance with a second embodiment of the present invention.

FIG. 3C shows a schematic drawing of the power shunt EMI filter in accordance with a third embodiment of the present invention.

FIG. 4A shows a schematic drawing of the power shunt EMI filter in accordance with a fourth embodiment of the present invention.

FIG. 4B shows a schematic drawing of the power shunt EMI filter in accordance with a fifth embodiment of the present invention.

FIG. 4C shows a schematic drawing of the power shunt EMI filter in accordance with a sixth embodiment of the present invention.

FIG. 5A shows a schematic drawing of the power shunt EMI filter in accordance with a seventh embodiment of the present invention.

FIG. 5B shows a schematic drawing of the power shunt EMI filter in accordance with a eighth embodiment of the present invention.

FIG. 5C shows a schematic drawing of the power shunt EMI filter in accordance with a ninth embodiment of the present invention.

FIG. 6A shows a schematic drawing of the power shunt EMI filter in accordance with a tenth embodiment of the present invention.

FIG. 6B shows a schematic drawing of the power shunt EMI filter in accordance with an eleventh embodiment of the present invention.

FIG. 6C shows a schematic drawing of the power shunt EMI filter in accordance with a twelfth embodiment of the present invention.

FIG. 7 shows a detailed circuit diagram of the power shunt EMI filter in accordance with FIG. 6B.

FIG. 8 shows a detailed circuit diagram of the power shunt EMI filter in accordance with FIG. 3C.

FIG. 9 shows experimental results of S-parameters response of the power shunt EMI filter in accordance with FIG. 7.

FIG. 10 shows experimental results of phase measured of the power shunt EMI filter in accordance with FIG. 7.

FIG. 11 shows experimental results of S-parameters response of the power shunt EMI filter in accordance with FIG. 8.

FIG. 12 shows experimental results of phase measured of the power shunt EMI filter in accordance with FIG. 8.

### DESCRIPTION OF THE PREFERRED EMBODIMENTS

Reference will now be made in detail to the preferred embodiments of the present invention, examples of which are illustrated in the accompanying drawings. Wherever possible, the same reference numbers are used in the drawings and the description to refer to the same or like parts.

The embodiments described below are illustrated to demonstrate the technical contents and characteristics of the present invention and to enable the persons skilled in the art to understand, make, and use the present invention. However, it shall be noticed that, it is not intended to limit the scope of the present invention. Therefore, any equivalent modification or variation according to the spirit of the present invention is to be also included within the scope of the present invention.

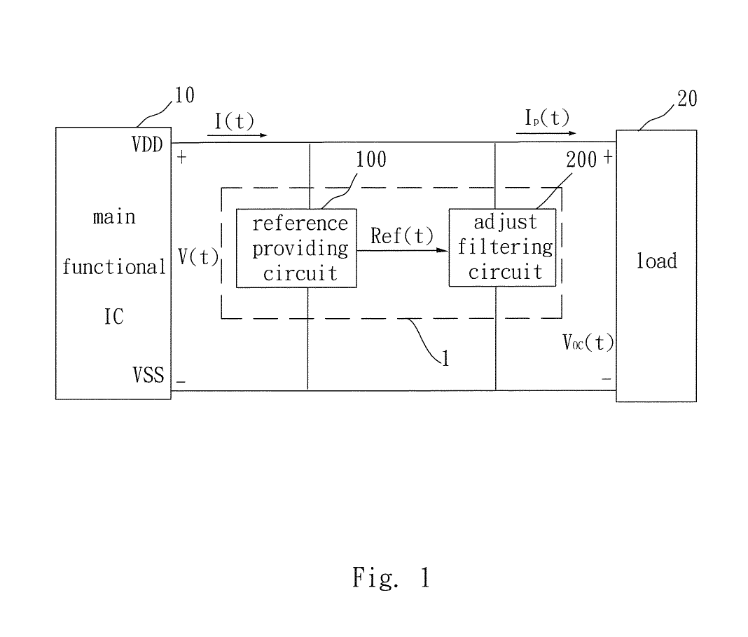

Please refer to FIG. 1, which shows a schematic drawing of the power shunt EMI filter in accordance with one embodiment of the present invention. As shown in FIG. 1, the power shunt EMI filter 1 is electrically connected to a power feeding line VDD of a main functional IC 10 and a load 20. After the main functional IC 10 is driven by a power source supplied by the power feeding line VDD, it generates an output voltage and an output current, wherein the output voltage is involved with an output voltage interference V(t), and the output current is involved with an output current interference I(t), respectively. Since the harmonic waveforms generated from the power source result in small-signals, a phase difference Φ_{c} exits between the output voltage interference V(t) and the output current interference I(t). The power shunt EMI filter 1 of the present invention is mainly designed for eliminate the phase difference Φ_{c}. As such after being filtered by power shunt EMI filter 1, the amplitude of the output voltage interference V(t) and the output current interference I(t) can be adjusted to be minimum such that the output voltage and the output current can process synchronously. As a result, when the load 20 receives signals as the voltage signal V_{oc}(t) and the current signal Iₚ(t) they are merely direct current (DC) signals. To be more specific, the power shunt EMI filter 1 comprises a reference providing circuit 100 and at least one adjust filtering circuit 200. The reference providing circuit 100 is electrically coupled to the main functional IC 10 and generates a reference signal Ref(t) based on the output voltage interference V(t) and/or the output current interference I(t). In other words, when the signal that the reference providing circuit 100 obtains is the output voltage interference V(t), the reference signal Ref(t) it outputs is a voltage signal. Contrarily, when the signal that the reference providing circuit 100 obtains is the output current interference I(t), then the reference signal Ref(t) it outputs is a current signal. The at least one adjust filtering circuit 200 is connected in parallel to the reference providing circuit 100 to receive the reference signal Ref(t). As such, the adjust filtering circuit 200 can calculate the eigenvalues of the output voltage interference V(t) and/or the output current interference I(t) based on the reference signal Ref(t) so as to adjust the phase difference Φ(I)_{c} between the output voltage interference V(t) and the output current interference I(t) to be zero. At last, the signals, i.e. V_{oc}(t) and Iₚ(t) that the load 20 receives are DC signals without any interferences and harmonics involved.

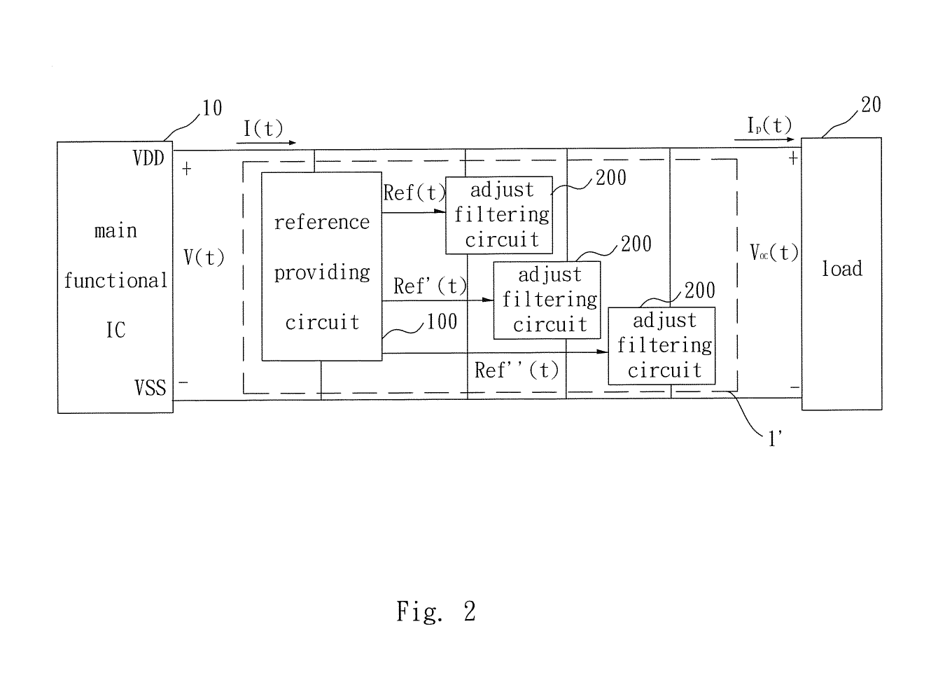

It should be noticed that the numbers of adjust filtering circuit 200 of the present invention are not limited. In other words, the power shunt EMI filter of the present invention may further comprise a plurality of adjust filtering circuits 200 connected in parallel to each other as shown in FIG. 2. FIG. 2 shows another embodiment of the present invention, in which the power shunt EMI filter 1′ comprises the reference providing circuit 100 and a plurality of adjust filtering circuits 200. Each adjust filtering circuit 200 is electrically coupled to the reference providing circuit 100 for receiving its output reference signal Ref(t), Ref′(t), Ref″(t) respectively in order to proceed to calculate the eigenvalues of the output voltage interference and/or the output current interference. To simplify and well explain the technical contents of calculating those eigenvalues, the present invention merely provides the structure that the power shunt EMI filter comprises single adjust filtering circuit 200 to show as an exemplary embodiment for detailed descriptions.

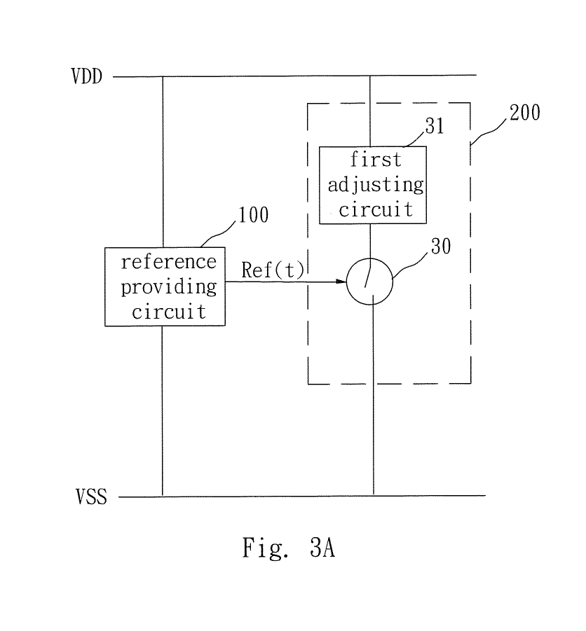

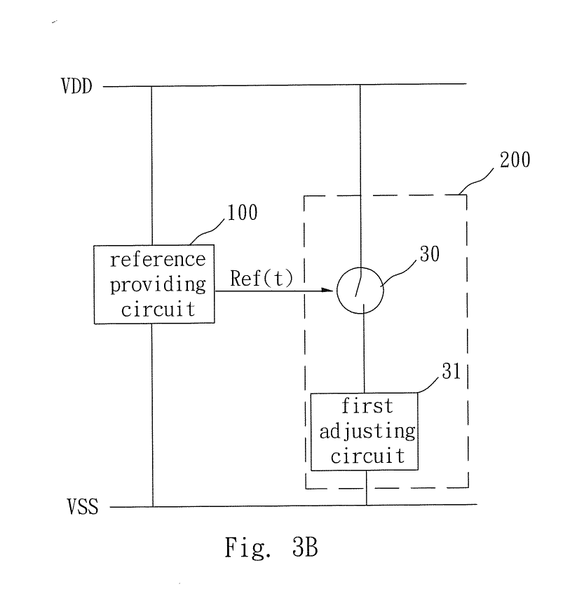

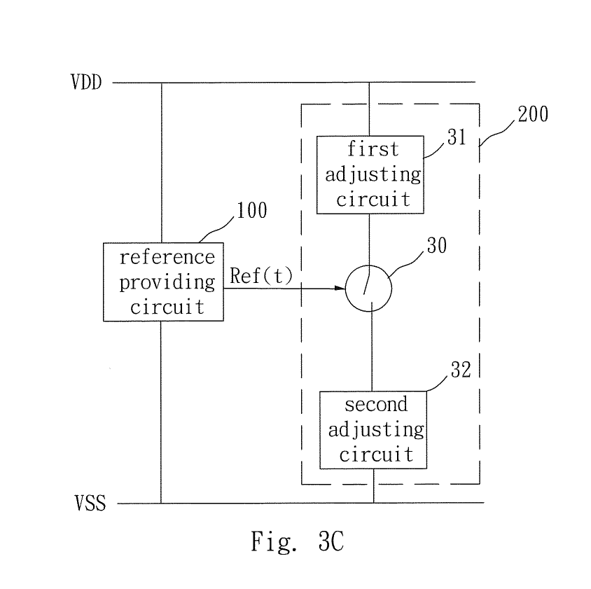

First of all, a detailed structure of the adjust filtering circuit 200 is disclosed. Please refer to FIG. 3A and FIG. 3B, in which the adjust filtering circuit 200 comprises a controlling switch 30 and at least one first adjusting circuit 31, and the controlling switch 30 and the first adjusting circuit 31 are connected in series between the power feeding line VDD and a ground line VSS. According to one embodiment of the present invention, the first adjusting circuit 31 can be disposed between the controlling switch 30 and the power feeding line VDD as shown in FIG. 3A, or between the controlling switch 30 and the ground line VSS as shown in FIG. 3B. Moreover, the adjust filtering circuit 200 may further comprise at least one second adjusting circuit 32, which is connected in series with the controlling switch 30 and the first adjusting circuit 31, such that the controlling switch 30, the first adjusting circuit 31 and the second adjusting circuit 32 are all in series between the power feeding line VDD and the ground line VSS as shown in FIG. 3C.

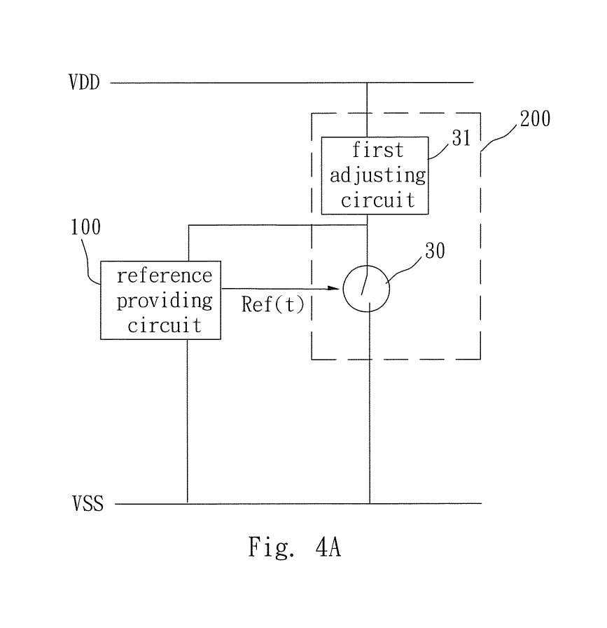

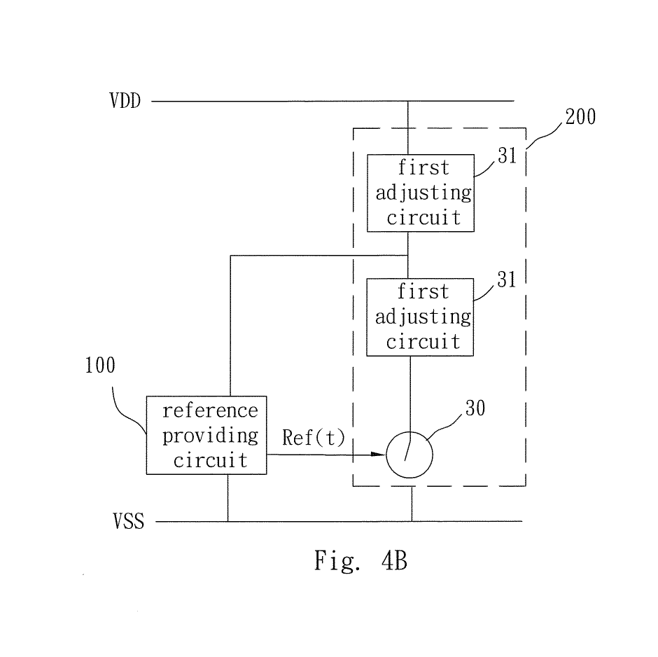

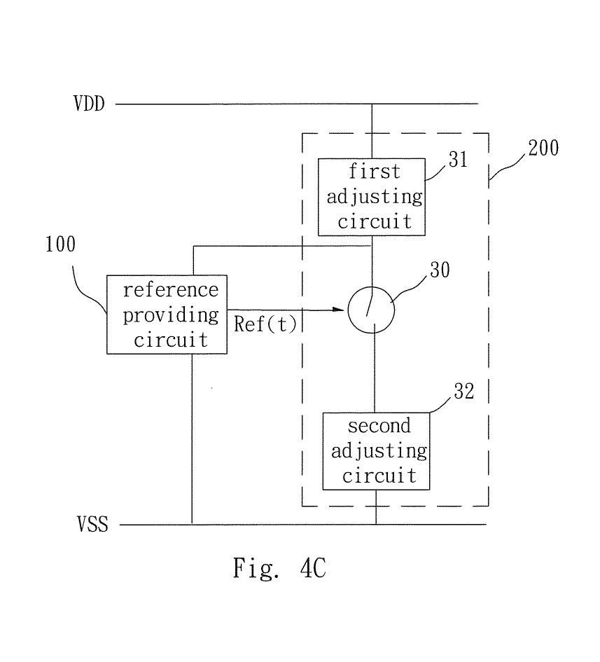

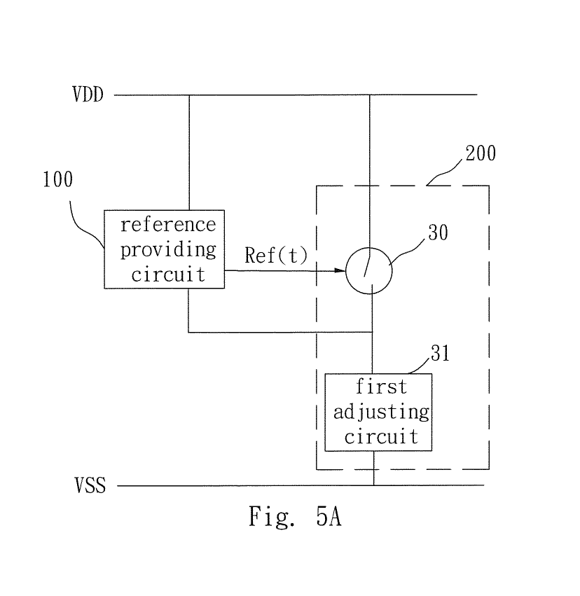

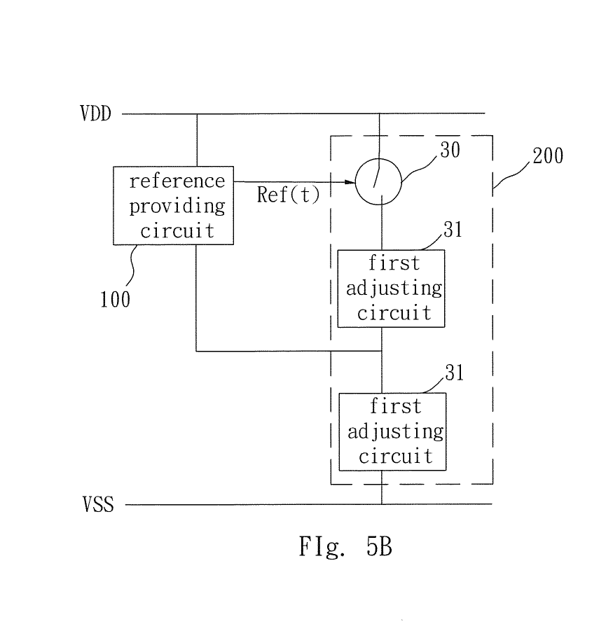

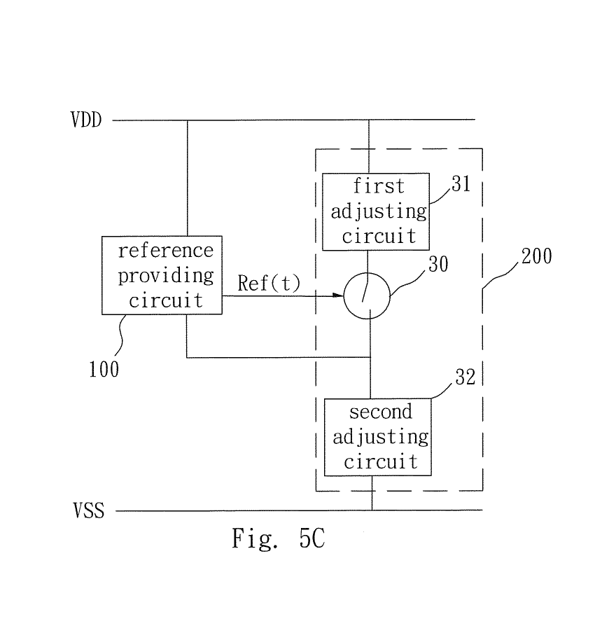

On the other hand, the present invention is not limited to how the controlling switch 30, the first adjusting circuit 31 and the second adjusting circuit 32 are connected to each other or how many they are. For example, please refer to FIG. 4A˜FIG. 4C and FIG. 5A˜FIG. 5C for some more embodiments of the present invention. In details, FIG. 4A shows an embodiment that modified the embodiment of FIG. 3A such that the reference providing circuit 100 is only connected to the ground line VSS. FIG. 4B shows an embodiment that the power shunt EMI filter of the present invention comprises more than one first adjusting circuit 31. FIG. 4C shows an embodiment that modified the embodiment of FIG. 3C such that the reference providing circuit 100 is only connected to the ground line VSS.

Similarly, FIG. 5A shows an embodiment that modified the embodiment of FIG. 3B such that the reference providing circuit 100 is only connected to the power feeding line VDD. FIG. 5B shows an embodiment that the power shunt EMI filter of the present invention comprises more than one first adjusting circuit 31. As for FIG. 5C, it shows an embodiment that modified the embodiment of FIG. 3C such that the reference providing circuit 100 is only connected to the power feeding line VDD.

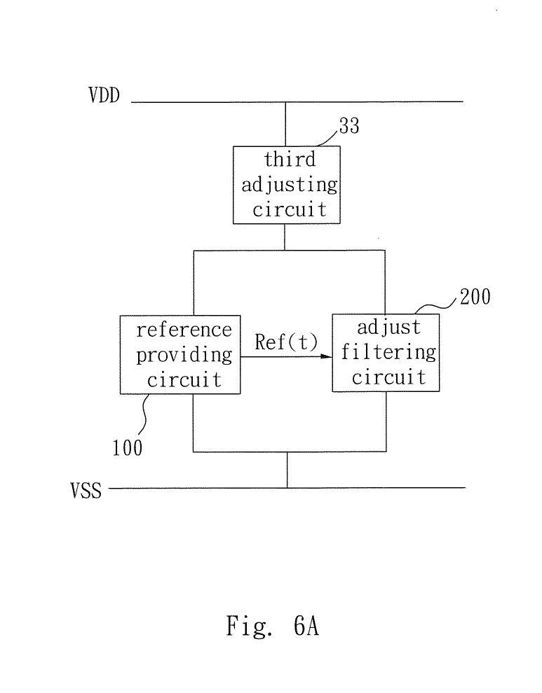

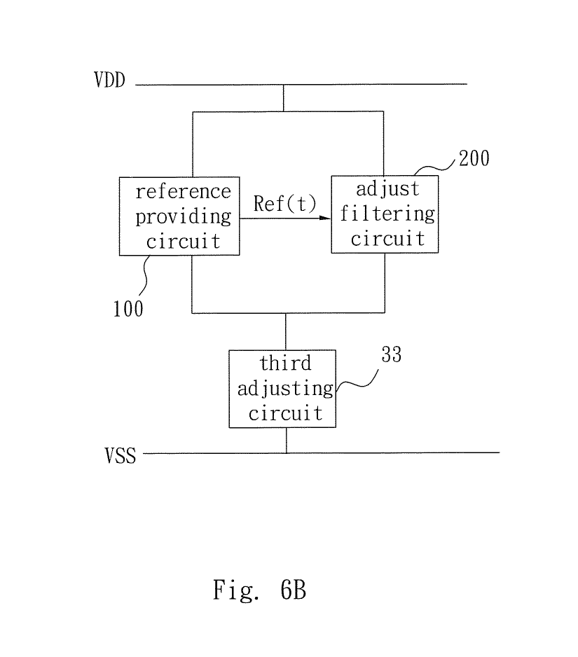

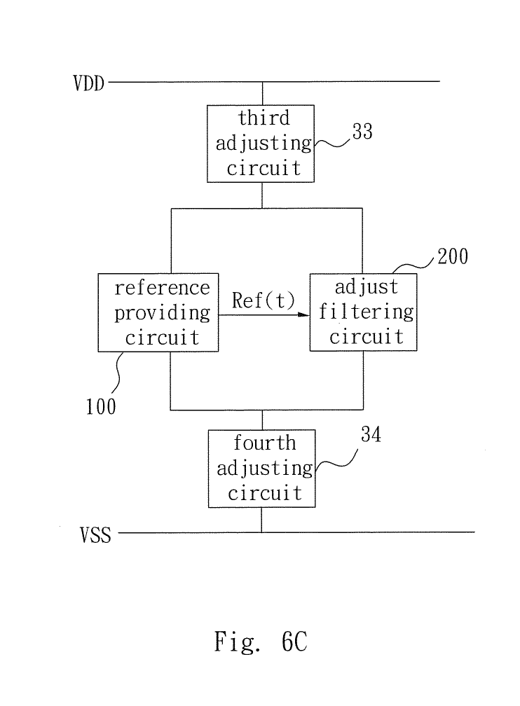

In addition to the reference providing circuit 100 and the adjust filtering circuit 200, the power shunt EMI filter of the present invention may further comprise at least one third adjusting circuit 33 and/or at least one fourth adjusting circuit 34, in which the embodiments are shown as FIG. 6A˜6C. In details, FIG. 6A shows an embodiment that the power shunt EMI filter of the present invention comprises one third adjusting circuit 33, and the third adjusting circuit 33 is connected between the power feeding line VDD and the adjust filtering circuit 200. FIG. 6B shows an embodiment that the power shunt EMI filter of the present invention comprises one third adjusting circuit 33, and the third adjusting circuit 33 is connected between the adjust filtering circuit 200 and the ground line VSS. As for FIG. 6C, it shows an embodiment that the power shunt EMI filter of the present invention comprises both a third adjusting circuit 33 and a fourth circuit 34, wherein the third adjusting circuit 33, the fourth circuit 34 and the adjust filtering circuit 200 are all connected in series between the power feeding line VDD and the ground line VSS. Therefore, to sum up, by optionally disposing the first adjusting circuit, the second adjusting circuit, the third adjusting circuit, and/or the fourth adjusting circuit which are composed of passive elements (for example, resistors, inductor, and/or inductors), when the controlling switch and the reference providing circuit are aimed to provide a dependent voltage-current curve and the reference signal is output, the present invention is able to be used for showing excellent performance in eliminating those interferences generated in the power feeding line of the power source. The detailed descriptions of how the power shunt EMI filter of the present invention works to eliminate interferences are discussed below.

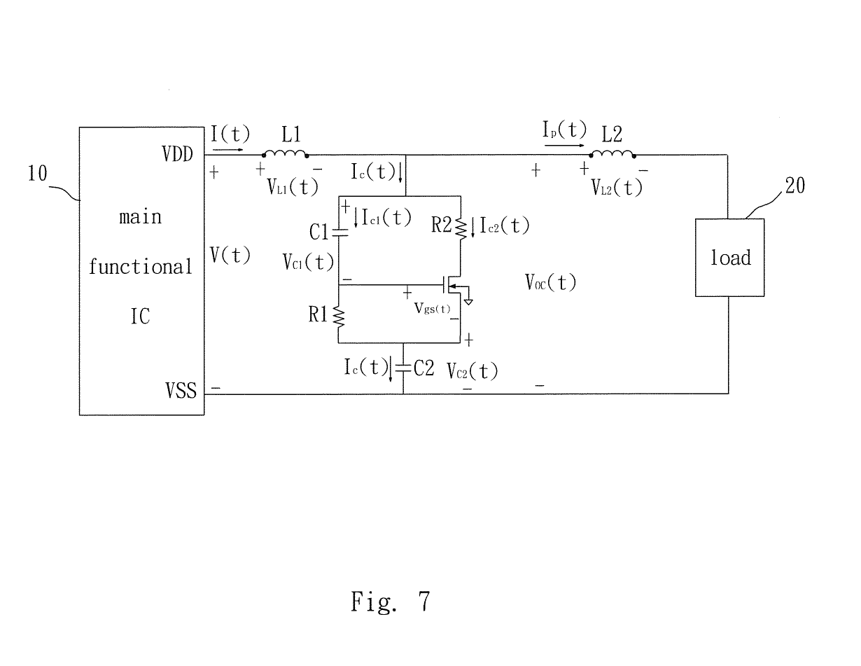

First, please refer to FIG. 7, which shows a detailed structure of the power shunt EMI filter according to FIG. 6B of the present invention. As shown in FIG. 7, the reference providing circuit 100 comprises a reference capacitor C1 and a reference resistor R1 connected in series. The adjust filtering circuit 200 comprises a controlling switch 30, which is coupled to a node where the reference capacitor C1 and the reference resistor R1 are connected, and a second resistor R2 connected between the power feeding line VDD and the controlling switch 30. In this embodiment as shown in FIG. 7, the adjust filtering circuit 200 comprises only one first adjusting circuit 31 (i.e. the second resistor R2), and there is no second adjusting circuit. A second capacitor C2 is further connected to the reference resistor R1, the controlling switch 30 and the ground line VSS. According to the embodiment of the present invention, the second capacitor C2 acts like the previously said third adjusting circuit 33. As for the controlling switch 30, it can be implemented by using a N-type metal oxide semiconductor (N MOS), a P-type metal oxide semiconductor (P MOS) or bipolar junction transistor (BJT). As long as the element is able to receive the reference signal from the reference providing circuit 100 and to form a dependent voltage or current curve accordingly, it can be adopted to use as the controlling switch 30. This embodiment shown in FIG. 7 merely considers a NMOS for an exemplary embodiment but the present invention is apparently not limited thereto.

When considering a NOS as the controlling switch 30, agate of the NMOS can be connected to any point within the reference providing circuit 100 for example, to a node where the reference capacitor C1 and the reference resistor R1 are jointed) to receive the reference signal as a reference voltage V_{gs}(t) to be its gate bias. The gate bias should be well controlled so that the NMOS can operate in different regions, for example, a linear region or so-called a non-saturation region, a saturation region, or an active region. At the time, the NMOS may act like a current switch which is voltage-coupled, having its on-current varying with the reference voltage. As such, the present invention employs a voltage-current characteristic of the NMOS to form a non-linear equation. Since the branch currents I_{c1}(t), I_{c2}(t) are dependent based on the voltage-current characteristic of the NMOS, a solution to the quadratic equation will be an intersection of a conic and a straight line. Thus, by properly adjusting the values of those passive elements used in the proposed circuit, the solution can be found. Furthermore, since the output voltage signal V_{oc}(t) is able to define an equation (1) and v₀, the proposed adjust filtering circuit of the present invention that is dominated by the NMOS can perform to adjust the values of those passive elements by calculating the voltage/current eigenvalues in order to control and minimize fluctuations of i₀ and v₀ The calculations are processed according to the equations (1)

$$\begin{matrix}I ( t ) = {I}_{0} + {i}_{0} {e}^{j wt} & ( 1 ) \\ {I}_{c} ( t ) = {i}_{c} {e}^{j ( wt + {φ}_{c} )} & ( 2 ) \\ {V}_{oc} ( t ) = {V}_{0} + {v}_{0} {e}^{j ( wt + {φ}_{0} )} , \\ {φ}_{0} = f ( {i}_{0} , {v}_{0} ) & ( 3 ) \\ Ic ( t ) = C 2 \cdot \frac{d {V}_{C 2} ( t )}{d t} & ( 4 ) \\ {I}_{c 1} ( t ) = C 1 \cdot \frac{d {V}_{C 1} ( t )}{d t} & ( 5 ) \\ Ic ( t ) = {I}_{c 1} ( t ) + {I}_{c 2} ( t ) & ( 6 ) \\ {I}_{p} ( t ) = I ( t ) - {I}_{c} ( t ) & ( 7 ) \\ {I}_{c 2} ( t ) = \frac{1}{2} {μ}_{n} {C}_{ox} \frac{W}{L} \{ 2 ( R 1 \cdot {I}_{c 1} ( t ) \cdot {V}_{i} ) \cdot [ {V}_{oc} ( t ) - R 2 \cdot {I}_{c 2} ( t ) - {V}_{C 2} ( t ) ] - {[ {V}_{oc} ( t ) - R 2 \cdot {I}_{c 2} ( t ) - {V}_{C 2} ( t ) ]}^{2} \} & ( 8 ) \\ {V}_{oc} ( t ) = {V}_{C 1} ( t ) + {V}_{C 2} ( t ) + R 1 \cdot C 1 \cdot \frac{d {V}_{C 1} ( t )}{d t} = L 2 \cdot \frac{d ⌊ I ( t ) - {I}_{c} ( t ) ⌋}{d t} + [ I ( t ) - {I}_{c} ( t ) ] \cdot ( {Z}_{R} + {jZ}_{l} ) & ( 9 )\end{matrix}$$

In equations (1) to (9), it defines I_{c}(t), I_{c1}(t), I_{c2}(t) as the values of current that flowing through the second capacitor C2 the reference capacitor C1 and the second resistor R2, respectively. V_{C1}(t), V_{C2}(t), V_{L1}(t), V_{L2}(t) are the values of voltage drops across the reference capacitor C1, the second capacitor C2, the inductor L1, and the inductor L2, respectively. μₙ, Cₒₓ, W, L are relatively known as transistor parameters of the NMOS. Therefore, by performing a calculation according to the above equations (1) to (9) to find a solution to i₀ and v₀ when setting Φ_{c} to be zero, the effective power shunt EMI filter of the present invention is well designed. Practically, the circuit designers nowadays are more likely to use simulation tools such as SPICE to search for an intersection solution to the above equations (1) to (9). When the values of the reference capacitor C1, the reference resistor R1, the second capacitor C2 and the second resistor R2 are found such that the phase difference Φ_{c} fits zero, it is indicating that these passive elements used to compose the filter forms a successful power shunt EMI filter that can effectively eliminate interferences and harmonics occurred in the power line at the power source. As a result, the output voltage and the output current of the main functional IC can accordingly process synchronously without any interference involved.

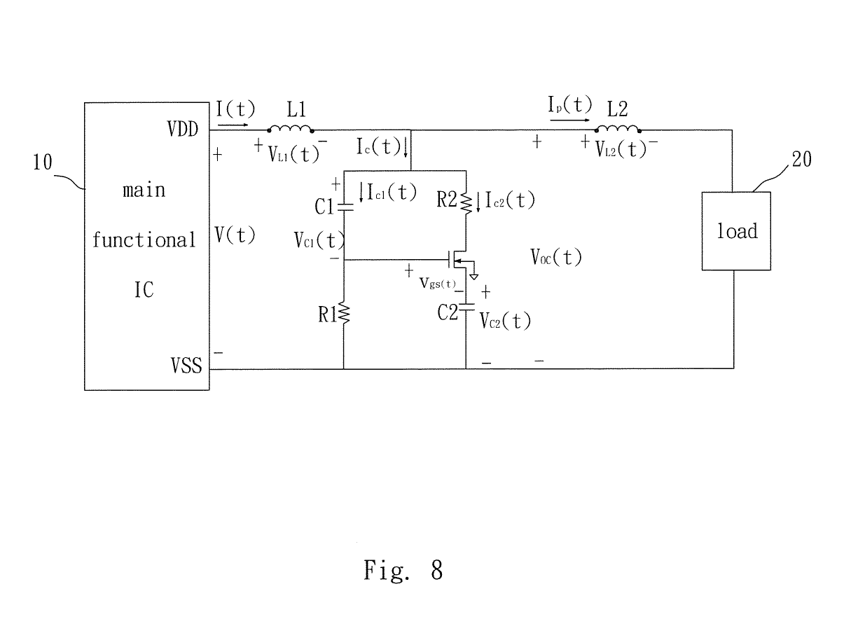

Furthermore, please refer to FIG. 8, which shows a detailed structure of the power shunt EMI filter according to FIG. 3C of the present invention. As shown in FIG. 8, the reference providing circuit 100 comprises a reference capacitor C1 and a reference resistor R1 connected in series. The adjust filtering circuit 200 comprises a controlling switch 30, a second resistor R2 and a second capacitor C2, wherein the controlling switch 30 is coupled to a node where the reference capacitor C1 and the reference resistor R1 are connected; the second resistor R2 is connected between the power feeding line VDD and the controlling switch 30; and the second capacitor C2 is connected between a source of the controlling switch 30 and a ground line VSS. With respect to FIG. 3B, it is apparent that the adjust filtering circuit 200 in this embodiment of FIG. 8 comprises both a first adjusting circuit 31 (i.e. the second resistor R2), and a second adjusting circuit 32 (i.e. the second capacitor C2). Neither a third adjusting circuit or a fourth adjusting circuit is disposed (as shown in short-circuited). According to an embodiment of the present invention when considering the controlling switch 30, it is able to be implemented by using a N-type metal oxide semiconductor (N MOS), a P-type metal oxide semiconductor (P MOS) or hi polar junction transistor (BJT). As long as the element is able to receive the reference signal from the reference providing circuit 100 and to form a dependent voltage or current curve accordingly, it can be adopted to use as the controlling switch 30. This embodiment shown in FIG. 8 merely considers a NMOS for an exemplary embodiment but the present invention is apparently not limited thereto.

As previously described in FIG. 7, a gate of the NMOS can be connected to any point within the reference providing circuit 100 (for example, to a node where the reference capacitor C1 and the reference resistor R1 are jointed) to receive the reference signal as a reference voltage V_{gs}(t) to be its gate bias. The gate bias should be well controlled so that the NMOS acts like a current switch which is voltage-coupled, having its on-current varying with the reference voltage. As such, the present invention employs a voltage-current characteristic of the NMOS to form a non-linear equation. Based on these, by calculating the voltage/current eigenvalues according to the equations (10) to (18) provided below, the power shunt EMI filter of the present invention successfully controls and minimizes fluctuations of i₀ and v₀ such that interferences and harmonics occur at the power source can be eliminated.

$$\begin{matrix}I ( t ) = {I}_{0} + {i}_{0} {e}^{j wt} & ( 10 ) \\ {I}_{c} ( t ) = {i}_{c} {e}^{j ( wt + {φ}_{c} )} & ( 11 ) \\ {V}_{oc} ( t ) = {V}_{0} + {v}_{0} {e}^{j ( wt + {φ}_{0} )} , \\ {φ}_{0} = f ( {i}_{0} , {v}_{0} ) & ( 12 ) \\ Ic ( t ) = C 2 \cdot \frac{d {V}_{C 2} ( t )}{d t} & ( 13 ) \\ {I}_{c 1} ( t ) = C 1 \cdot \frac{d {V}_{C 1} ( t )}{d t} & ( 14 ) \\ Ic ( t ) = {I}_{c 1} ( t ) + {I}_{c 2} ( t ) & ( 15 ) \\ {I}_{p} ( t ) = I ( t ) - {I}_{c} ( t ) & ( 16 ) \\ {I}_{c 2} ( t ) = \frac{1}{2} {μ}_{n} {C}_{ox} \frac{W}{L} \{ 2 ( R 1 \cdot {I}_{c 1} ( t ) \cdot {V}_{i} ) \cdot [ {V}_{oc} ( t ) - R 2 \cdot {I}_{c 2} ( t ) - {V}_{C 2} ( t ) ] - {[ {V}_{oc} ( t ) - R 2 \cdot {I}_{c 2} ( t ) - {V}_{C 2} ( t ) ]}^{2} \} & ( 17 ) \\ {V}_{oc} ( t ) = {V}_{C 1} ( t ) + {V}_{C 2} ( t ) + R 1 \cdot C 1 \cdot \frac{d {V}_{C 1} ( t )}{d t} = L 2 \cdot \frac{d ⌊ I ( t ) - {I}_{c} ( t ) ⌋}{d t} + [ I ( t ) - {I}_{c} ( t ) ] \cdot ( {Z}_{R} + {jZ}_{l} ) & ( 18 )\end{matrix}$$

Therefore, by performing a calculation according to the above equations (10) to (18) to find a solution to i₀ and v₀ when setting Φ_{c} to be zero, the effective power shunt EMI filter of the present invention is well designed. Practically, the circuit designers nowadays are more likely to use simulation tools such as SPICE to search for an intersection solution to the above equations (10) to (18). When the values of the reference capacitor C1, the reference resistor R1, the second capacitor C2 and the second resistor R2 are found such that the phase difference Φ_{c} fits zero, it is indicating that these passive elements used to compose the filter forms a successful power shunt EMI filter that can effectively eliminate interferences and harmonics occurred in the power line at the power source. Applying the similar sense and methodology, other embodiments of the present invention can also be implemented by the calculation of voltage/current eigenvalues. Those skilled in the art can figure their own designs based on the present invention without departing from the scope or spirit of the invention, nevertheless, still falling within the scope of the invention and its equivalent. Next, the present invention is verified with experimental results provided below to prove that the power shunt EMI filter of the present invention is in deed a well-designed and effective filter that can successfully eliminate interferences at the power source.

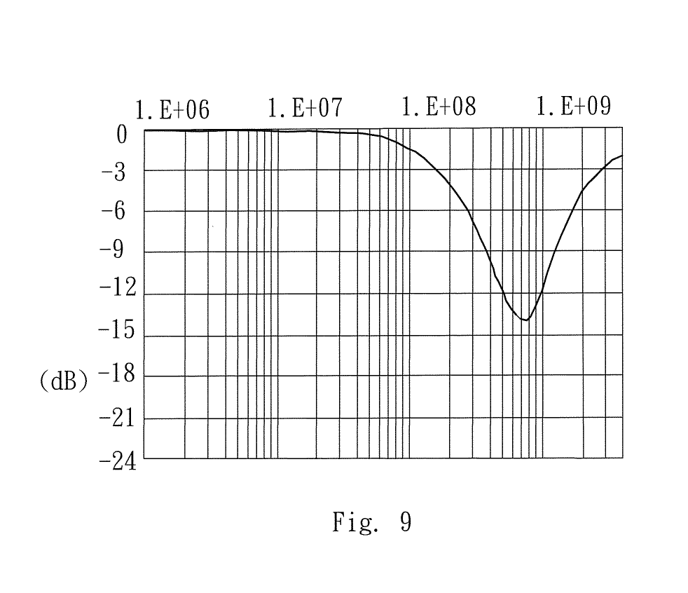

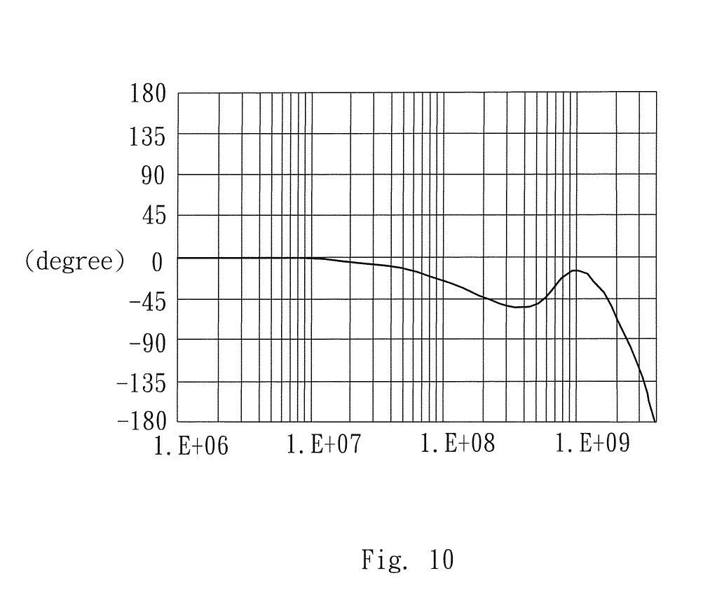

Regarding the embodiment of FIG. 7, the main functional IC 10 is considered as an input end, and the load 20 is considered as an output end. The result of S-parameter is measured and recorded when setting a 50Ω impedance as shown in FIG. 9 and FIG. 10. In these two figures, it is obvious that interferences having frequency range from 280 MHz to 1.6 GHz are downed to less than 6 dB. Also, the amplitude of interferences having frequency range within this interval is weakened by more than 50%, showing that the present invention performs an extraordinary effect on eliminating EMI occurring at the power source.

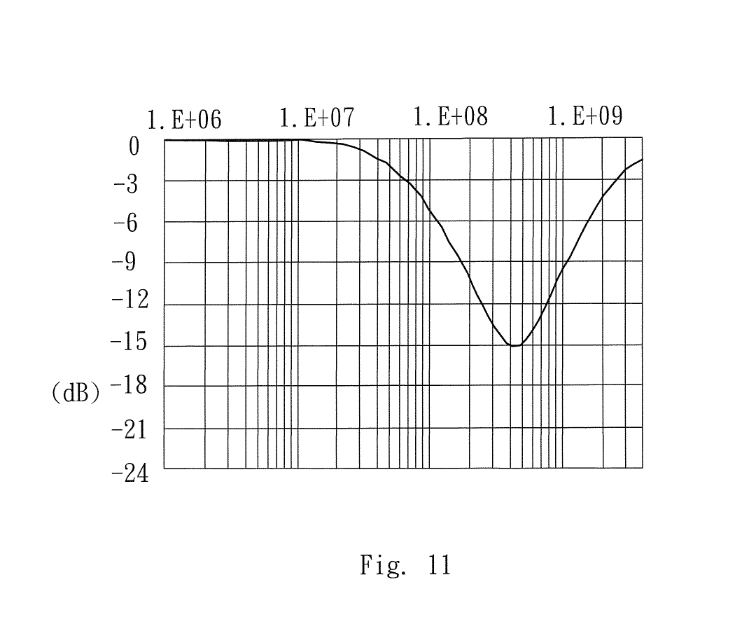

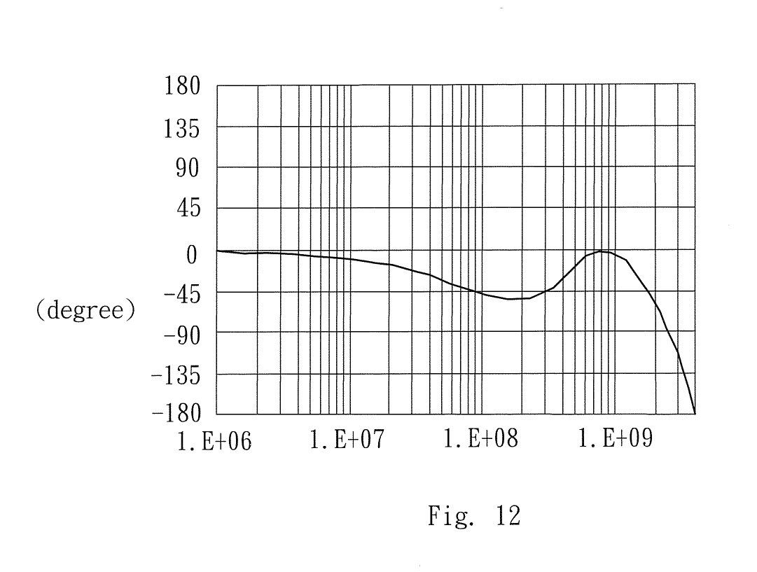

Similarly, FIG. 11 shows an experimental result of S₂₁ response and FIG. 12 shows an experimental result of phase measured according to the embodiment of FIG. 8. From these experimental results FIG. 11 and FIG. 12 show, it also proves that the interferences having frequency range from 200 MHz to 1.4 GHz can be downed to less than 6 dB, meaning the amplitude is shrunk to more than 50% off. As a result, it is believed that the power shunt EMI filter of the present invention is advantageous of suppressing the EMI occurred at the power source and meanwhile maintaining a fine power integrity, which is highly competitive for IC technology, industries and researches developed in the future.

As a result, to sum up, the present invention indeed provides a novel and inventive power shunt EMI filter which has never been seen or proposed ever before. By employing the proposed power shunt EMI filter, it is able not only to eliminate the interferences occurred at the power source but also to maintain a complete power integrity, solving the prior issues successfully. Therefore, when compared to the prior arts which only adopts “try and error” methods to layout the EMI filter structure, the present invention apparently shows much more effective performance in both low fabrication cost and low circuit complexity. In addition, the interferences at high frequencies (ranging from 100 MHz to GHz) are almost reduced. Thus, it is believed that the present invention is instinct, effective and highly competitive for IC technology and industries in the market nowadays.

It will be apparent to those skilled in the art that various modifications and variations can be made to the present invention without departing from the scope or spirit of the invention. In view of the fore going, it is intended that the present invention cover modifications and variations of this invention provided they fall within the scope of the invention and its equivalent.

What is claimed is:

1. A power shunt electromagnetic interference filter, which is electrically connected to a power feeding line of a main functional IC and a load, wherein said main functional IC generates an output voltage and an output current after said main functional IC is driven by a power source supplied by said power feeding line; said output voltage is involved with an output voltage interference; said output current is involved with an output current interference; and a phase difference exits between said output voltage interference and said output current interference owing to harmonics interferences generated at said power source, said power shunt electromagnetic interference filter comprising:
a reference providing circuit, electrically coupled to said main functional IC and outputting a reference signal according to said output voltage interference and/or said output current interference; and
at least one adjust filtering circuit connected in parallel to said reference providing circuit for receiving said reference signal, wherein said adjust filtering circuit accordingly calculates eigenvalues of said output voltage interference and/or said output current interference such that said phase difference is adjusted to zero, amplitudes of said output voltage interference and said output current interference are adjusted to zero as well, and an output voltage signal and an output current signal that said load receives are merely direct current (DC) signal without any interferences or harmonics involved.

2. The power shunt electromagnetic interference filter of claim 1, said adjust filtering circuit further comprising a controlling switch and at least one first adjusting circuit, wherein said controlling switch and said first adjusting circuit are connected in series between said power feeding line and a ground line.

3. The power shunt electromagnetic interference filter of claim 2, wherein said first adjusting circuit is connected between said power feeding line and said controlling switch, and said controlling switch is connected to said reference providing circuit for receiving said reference signal.

4. The power shunt electromagnetic interference filter of claim 3, wherein said adjust filtering circuit further comprises a second adjusting circuit, and said second adjusting circuit is connected between said controlling switch and said ground line.

5. The power shunt electromagnetic interference filter of claim 2, wherein said first adjusting circuit is connected between said controlling switch and said ground line, and said controlling switch is connected to said reference providing circuit for receiving said reference signal.

6. The power shunt electromagnetic interference filter of claim 5, wherein said adjust filtering circuit further comprises a second adjusting circuit, and said second adjusting circuit is connected between said controlling switch and said power feeding line.

7. The power shunt electromagnetic interference filter of claim 2, wherein said first adjusting circuit is composed of passive elements selected from a group consisting of resistors, inductor and inductors.

8. The power shunt electromagnetic interference filter of claim 4, wherein said second adjusting circuit is composed of passive elements selected from a group consisting of resistors, inductor and inductors.

9. The power shunt electromagnetic interference filter of claim 1, further comprising a plurality of said adjust filtering circuit such that said plurality of adjust filtering circuit calculate eigenvalues of said output voltage interference and/or said output current interference to adjust said phase difference to be zero.

10. The power shunt electromagnetic interference filter of claim 1, wherein said reference signal is a voltage signal or a current signal.

11. The power shunt electromagnetic interference filter of claim 2, wherein said reference providing circuit comprises a reference resistor and a reference capacitor, said reference resistor and said reference capacitor are connected in series, and said controlling switch is coupled to a node where said reference resistor and said reference capacitor are jointed.

12. The power shunt electromagnetic interference filter of claim 2, wherein said controlling switch is a metal oxide semiconductor or bipolar junction transistor such that a voltage-current characteristic of said metal oxide semiconductor or bipolar junction transistor is adopted for calculating said eigenvalues, and said phase difference between said output voltage interference and said output current interference can be downed to be zero.

13. The power shunt electromagnetic interference filter of claim 1, further comprising a third adjusting circuit, wherein said third adjusting circuit and said adjust filtering circuit are connected in series between said power feeding line and a ground line.

14. The power shunt electromagnetic interference filter of claim 13, wherein said third adjusting circuit is connected between said power feeding line and said adjust filtering circuit, and said third adjusting circuit is composed of passive elements selected from a group consisting of resistors, inductor and inductors.

15. The power shunt electromagnetic interference filter of claim 14, further comprising a fourth adjusting circuit, which is connected between said adjust filtering circuit and said ground line.

16. The power shunt electromagnetic interference filter of claim 13, wherein said third adjusting circuit is connected between said adjust filtering circuit and said ground line, and said third adjusting circuit is composed of passive elements selected from a group consisting of resistors, inductor and inductors.

17. The power shunt electromagnetic interference filter of claim 16, further comprising a fourth adjusting circuit, which is connected between said adjust filtering circuit and said power feeding line.

18. The power shunt electromagnetic interference filter of claim 15, wherein said fourth adjusting circuit is composed of passive elements selected from a group consisting of resistors, inductor and inductors.

19. The power shunt electromagnetic interference filter of claim 6, wherein said second adjusting circuit is composed of passive elements selected from a group consisting of resistors, inductor and inductors.

20. The power shunt electromagnetic interference filter of claim 17, wherein said fourth adjusting circuit is composed of passive elements selected from a group consisting of resistors, inductor and inductors.
